(19) United States
(12) Patent Application Publication
(10) Pub. No.: US 2026/0159944 A1
(43) Pub. Date: Jun. 11, 2026

(54) SELECTIVE DEPOSITION OF SILICON NITRIDE

(71) Applicant: Applied Materials, Inc., Santa Clara, CA (US)

(72) Inventors: Aniruddh Shekhawat, Tempe, AZ (US); Ligang Gao, Chandler, AZ (US); Karthik Colinjivadi, Dublin, CA (US); Vahid Ghodsi Karbasdehi, Chandler, AZ (US); Bhaskar Jyoti Bhuyan, San Jose, CA (US)

(73) Assignee: Applied Materials, Inc., Santa Clara, CA (US)

(21) Appl. No.: 18/969,555

(22) Filed: Dec. 5, 2024

(51) Int. Cl. C23C 16/455; C23C 16/01; C23C 16/02; C23C 16/34

(52) U.S. Cl. CPC C23C 16/45531; C23C 16/01; C23C 16/0272; C23C 16/345

(57) ABSTRACT

Methods of forming devices by selective deposition of a third nitride material on a second nitride material over a first nitride material. An inhibitor is used to selectively passivate the first nitride material so that the third nitride material forms on the second nitride material. The inhibitor may be removed after deposition of the third nitride material.

### TECHNICAL FIELD

Embodiments of the disclosure generally relate to methods of forming interconnect structures in microelectronic devices. More particularly, embodiments of the disclosure are directed to methods of improving selective deposition of silicon nitride on one nitride surface relative to a different nitride surface during formation of interconnect structures in microelectronic devices.

### BACKGROUND

Multiple challenges impede power and performance improvements when scaling transistors and interconnects to the 3 nm node and beyond. Interconnects include metal lines that transfer current within the same device layer and metal vias that transfer current between layers. Pitch reduction narrows the width of both and increases resistance, and also increases the voltage drop across a circuit, throttling circuit speed and increasing power dissipation.

While transistor performance improves with scaling, the same cannot be said for interconnect metals. As dimensions shrink, interconnect via resistance can increase by a factor of 10. An increase in interconnect via resistance may result in resistive-capacitive (RC) delays that reduce performance and increases power consumption. A conventional interconnect structure includes a barrier layer deposited on the sidewalls of a gap that provides a via, where the sidewalls are made of a dielectric material. The barrier layer may provide good adhesion and prevent diffusion into the dielectric layer and other adverse interactions between the dielectric layers and may also include a metal liner deposited on the barrier layer. Increased via resistance remains an issue, especially in smaller features when barrier layers on sidewalls form an increasing percentage of the via volume.

Titanium nitride (TiN) is often used as a trench (or via) contact material with dielectric (e.g., silicon nitride (SiN)) sidewalls. For smaller node applications, shrinking the trench or via allows for greater device density and improved device performance. Currently, inhibiting deposition of a nitride material on one nitride surface relative to a second nitride surface can be difficult.

Accordingly, there is a need for methods for depositing material layers during formation of interconnect structures that improve performance of interconnects.

### SUMMARY

Embodiments of the disclosure are directed to methods of selectively depositing a film. The methods include exposing a substrate to an inhibitor to selectively passivate a first nitride material relative to a second nitride material, the first nitride material being different from the second nitride material. A third nitride material is deposited on the second nitride material.

Additional embodiments of the disclosure are directed to methods of selectively depositing a film. The methods include forming a self-assembled monolayer of an inhibitor in a structure on a substrate. The structure has a bottom of a first nitride material and sidewalls of a second nitride material. The self-assembled monolayer forms on the first nitride material selectively over the second nitride material. The first nitride material is different from the second nitride material. A third nitride material is deposited on the second nitride material.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A illustrates a portion of a microelectronic device during a stage of manufacture with one or more embodiments of the disclosure having a first nitride material surface containing impurities on a bottom of a gap;

FIG. 1B illustrates removal of the impurities from the first nitride material surface shown in FIG. 1A;

FIG. 1C illustrates deposition of an inhibitor (self-assembled monolayer) on the metal surface shown in FIG. 1B;

FIG. 1D illustrates a third nitride material formed on the second nitride materials of the sidewalls of the gap;

FIG. 1E illustrates removal of the inhibitor (self-assembled monolayer) in FIG. 1D; and

FIG. 2 illustrates a process flow diagram of a method of manufacturing a microelectronic device in accordance with one or more embodiments of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” and “wafer” are used interchangeably, both referring to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate (or otherwise generate or graft target chemical moieties to impart chemical functionality), anneal and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface. What a given substrate surface comprises will depend on what films are to be deposited, as well as the particular chemistry used.

As used in this specification and the appended claims, the terms “reactive gas”, “precursor”, “reactant”, and the like, are used interchangeably to mean a gas that includes a species which is reactive with a substrate surface. For example, a first “reactive gas” may simply adsorb onto the surface of a substrate and be available for further chemical reaction with a second reactive gas.

Some embodiments of the disclosure provide methods for decreasing the interconnect widths. Interconnects comprise metal lines that transfer current within the same device layer, and metal vias that transfer current between layers. These lines and vias are formed with conductive metal such as copper or cobalt in gaps formed within the device. In one or more embodiments, a dielectric layer comprises at least one feature defining a gap including sidewalls and a bottom. In one or more embodiments, the gap comprises the metal lines and the metal vias. In one or more embodiments, the metal lines have a sidewall and a bottom. In one or more embodiments, the metal vias have a sidewall and a bottom. As used in this specification and the appended claims, unless specified otherwise, reference to the “bottom of the gap” is intended to mean the bottom of the metal via, which is nearest the substrate.

As the technology node advances, for example, when scaling microelectronic devices and interconnects to the 3 nm node and beyond the back end of line (BEOL) includes new interfaces such as tungsten (W), molybdenum (Mo), and ruthenium (Ru). Improving self-assembled monolayer (SAM) selectivity on metal to low-k surfaces becomes more challenging, especially when these interfaces contain different kinds of impurities such as oxygen, carbon, nitrogen, fluorine, chlorine, etc.

Currently, there is no state-of-the-art technology for depositing silicon nitride (SiN) on a silicon nitride (SiN) layer selectively over a titanium nitride (TiN) layer. For example, there are no known techniques to inhibit silicon nitride (SiN) growth on titanium nitride (TiN) selectively over another silicon nitride (SiN) layer. Some embodiments of the disclosure advantageously provide chemistry that forms a self-assembled monolayer (SAM) selectively on the titanium nitride material and not on the silicon nitride material. Some embodiments use a titanium nitride pre-treatment process combined with SAM chemistry that enables selective growth of a nitride material on the nitride sidewalls of the feature and block growth on the nitride bottom of the feature.

Embodiments of the disclosure provide methods of forming interconnect structures in the manufacture of microelectronic devices. In one or more embodiments, microelectronic devices described herein comprise at least one top interconnect structure that is interconnected to at least one bottom interconnect structure. Embodiments of the disclosure provide microelectronic devices and methods of manufacturing microelectronic devices that improve device performance by, for example, reducing via width to allow for denser packing of the vias.

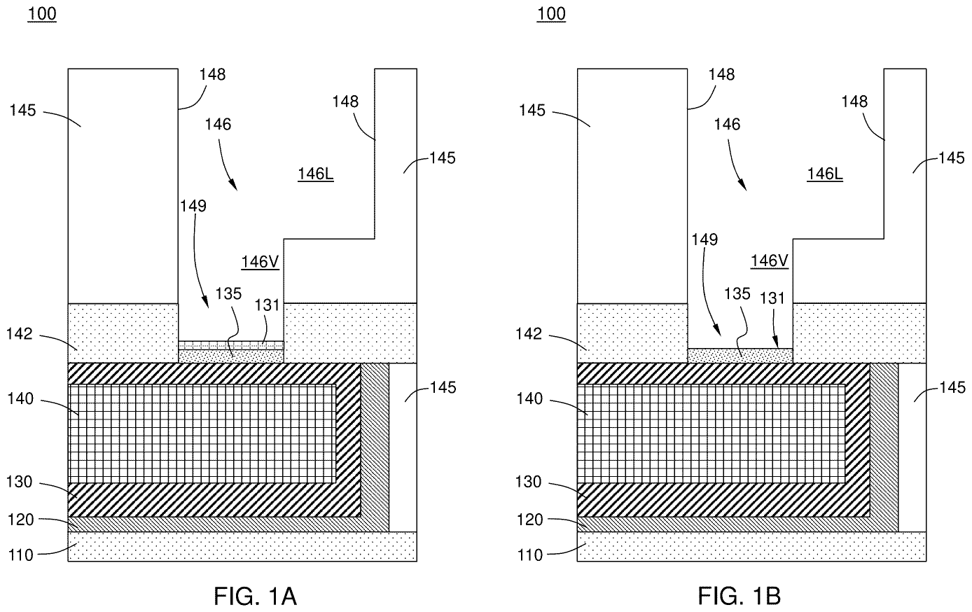

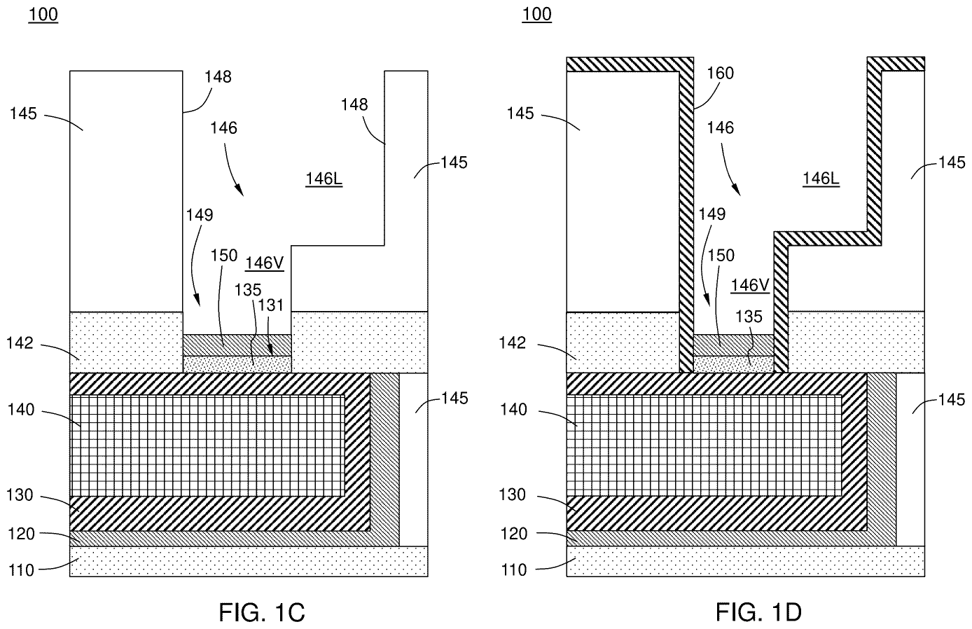

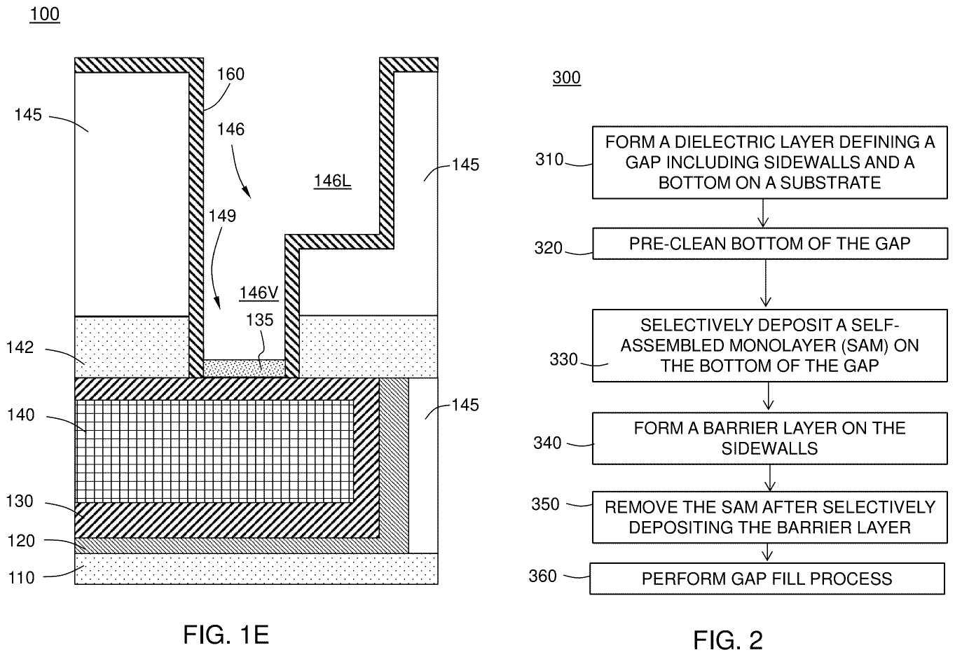

Methods of forming microelectronic devices are described herein with reference to FIGS. 1A-1E . FIG. 2 is a flow chart of an exemplary method of forming microelectronic devices with respect to FIGS. 1A-1E .

Referring to FIGS. 1A-1E , a portion of a microelectronic device 100 is shown during stages of manufacture, where the substrate is a substrate processing chamber, such as an atomic layer deposition processing chamber, a chemical vapor deposition processing chamber, a cyclical vapor deposition chamber, or a preclean chamber. In one or more embodiments, the substrate processing chamber comprises a local plasma source, a remote plasma source or both a local plasma source or a remote plasma source. The plasma source in some embodiments comprise an inductively coupled plasma source or a capacitively coupled plasma source. The plasma sources include one or more of a hydrogen, argon, H₂O, ammonia, neon, krypton, or helium gas supply.

During plasma treatment pressure in the substrate processing chamber in some embodiments, is from 0.1 mTorr to 10 Torr. The plasma in some embodiments comprises an inductively coupled plasma (ICP) and/or a capacitively coupled plasma (CCP) with or without an ion filter.

In one aspect, methods comprise forming a dielectric layer on a substrate, the dielectric layer comprising at least one feature defining a gap including sidewalls and a bottom including a metal surface, pre-cleaning the metal surface, selectively depositing a self-assembled monolayer (SAM) on the bottom of the gap and the metal surface, selectively depositing a barrier layer on the sidewalls but not on the metal surface, and removing the SAM after selectively depositing the barrier layer on the sidewalls.

In FIG. 1A, the microelectronic device 100 comprises a substrate 110, a barrier layer 120 on the substrate 110, a metal layer 130 on the barrier layer 120, a conductive filled gap 140, an aluminum oxide etch stop layer 142 on the metal layer 130 and/or conductive gap fill 140, a dielectric layer 145 on the aluminum oxide etch stop layer 142, the dielectric layer 145 comprising at least one feature defining a gap 146 including sidewalls 148 and a bottom 149. According to one or more embodiments, a metal surface 131 containing impurities is on the bottom 149 of the gap. In some embodiments, the impurities comprise a native oxide. It will be appreciated that in one or more embodiments, the conductive filled gap 140 forms a metal line that transfers current within the same device layer.

In one or more embodiments, the substrate 110 is a wafer, for example a semiconductor substrate. In one or more embodiments, the substrate 110 is an etch stop layer on a wafer. In one or more embodiments, the substrate 110 is an aluminum oxide etch stop layer on a wafer.

In one or more embodiments, the barrier layer 120 comprises tantalum nitride (TaN) or doped TaN. In one or more embodiments, the barrier layer 120 comprises tantalum nitride (TaN) formed by ALD.

In one or more embodiments, the metal layer 130 comprises one or more of ruthenium (Ru), copper (Cu), cobalt (cobalt), molybdenum (Mo), tantalum (Ta), or tungsten (W). In one or more embodiments, the metal layer 130 comprises one or more of copper (Cu), cobalt (cobalt), molybdenum (Mo), or tungsten (W). In one or more embodiments, a portion of the metal layer 130 is etched. In one or more embodiments, the blocking layer 150 is deposited on the portion of the metal layer 130 that is etched. In one or more embodiments, the conductive filled gap 140 comprises one or more of copper (Cu) or cobalt (Co).

In some embodiments, a first nitride material 135 is formed on the metal layer 130. The first nitride material 135 can be any suitable material including but not limited to barrier layers and liners. In some embodiments, the first nitride material 135 comprises one or more of titanium nitride (TiN), tungsten nitride (WN), or tantalum nitride (TaN). The skilled artisan will recognize that the formulae provided are identifying the atomic components are not representative of the empirical or molecular formulae of the compounds. For example, tungsten nitride (WN) includes molecular formulae W₂N, WN, WN₂, etc. In some embodiments, the first nitride material 135 comprises or consists essentially of titanium nitride (TiN). As used in this specification and the appended claims, the term “consists essentially of” means that the subject component (e.g., in this case, the first nitride material 135) is made of greater than or equal to 95%, 98% or 99% of the stated material (e.g., in this case, titanium nitride (TiN)).

In one or more embodiments, the etch stop layer 142 comprises one or more of silicon nitride, or aluminum nitride. In some embodiments, the etch stop layer 142 comprises or consists essentially of aluminum nitride (AlN). While the embodiments described herein include an etch stop layer 142, the skilled artisan will recognize that an etch stop layer 142 can be omitted so that the dielectric layer 145 directly contacts the underlying materials. The etch stop layer 142 may also be referred to as a fourth nitride material.

In one or more embodiments, a dielectric layer 145 is a second nitride material that is different from the first nitride material. In some embodiments, the second nitride material (dielectric layer 145) is a low-k dielectric material. In certain embodiments, the second nitride material (dielectric layer 145) comprises or consists essentially of silicon nitride (SiN). In some embodiments, the dielectric layer 145 is a porous or carbon-doped silicon nitride layer with a k value less than about 5. In one or more embodiments, the second nitride material (dielectric layer 145) is a multilayer structure. For example, in one or more embodiments, the second nitride material (dielectric layer 145) comprises a multilayer structure having one or more of a dielectric layer (e.g., dielectric layer 145, an etch stop layer (e.g., etch stop layer 142, which is the fourth nitride material), and a hard mask layer (not shown).

In one or more embodiments, the second nitride material (dielectric layer 145) comprises at least one feature defining a gap 146 including sidewalls 148 and a bottom 149. The Figures show substrates having a single feature for illustrative purposes, however, those skilled in the art will understand that there can be more than one feature. The shape of the feature can be any suitable shape including, but not limited to, trenches, cylindrical vias that, when filled with metal, transfer current between layers, and lines that transfer current within the same device layer. In some embodiments, the feature defines a gap 146 in the dielectric layer 145. The gap 146 in some embodiments defines a via portion 146V and a line portion 146L, but the embodiments shown are not intended to be limiting.

As used herein, the term “feature” means any intentional surface irregularity. Suitable examples of features include but are not limited to trenches which have a top, two sidewalls and a bottom, peaks which have a top and two sidewalls. Features can have any suitable aspect ratio (ratio of the depth of the feature to the width of the feature). In some embodiments, the aspect ratio is greater than or equal to about 5:1, 10:1, 15:1, 20:1, 25:1, 30:1, 35:1 or 40:1.

Referring to FIG. 1B, the first nitride material surface 131 has been cleaned by exposing the first nitride material surface 131 at the bottom 149 of the gap to a pre-cleaning process. As discussed above, in embodiments, the substrate is in a substrate processing chamber and the pre-cleaning process comprises exposing the first nitride material 135 including the first nitride material surface 131 to a cleaning gas selected from H₂O vapor, H₂O₂, WF₆, NH₃, MoCl₅, MoCl₆, WCl₅, WCl₆, SOCl_{2,} PCl₅ when the temperature in the substrate processing chamber is at or above 80° C., at or above 100° C., at or above 120° C., at or above 140° C., at or above 160° C., at or above 180° C., or at or above 200° C. In some embodiments, the temperature is in a range with an upper temperature value of to 450° C. In some embodiments, the pre-cleaning process comprises removing the surface oxides from the first nitride material 135 using a hydrogen (H₂) plasma. In some embodiments, the pre-cleaning process comprises exposing the first nitride material 135 to a plasma comprising or consisting essentially of hydrogen (H₂). After or during exposing the metal surface to the cleaning gas, the method further comprises exposing the metal surface to a plasma. Exposing the metal surface to a cleaning gas and to the plasma reduces impurities from the metal surface. The impurities on the metal surface according to embodiments include but are not limited to impurities selected from the group consisting of F, Cl, O, N, and C. in some embodiments, the first nitride material surface 131 comprises a native oxide of the first nitride material 135 and the pre-cleaning process removes the native oxide from the surface of the first nitride material 135.

Referring to FIG. 1C, the substrate 110 or electronic device 100 including the first nitride material 135 is exposed to an inhibitor to selectively passivate the first nitride material 135 relative to a second nitride material (dielectric layer 145) to form a passivation layer (e.g., a self-assembled monolayer (SAM)) 150 on the surface of the first nitride layer 135. In one or more embodiments, the SAM 150 is formed on the first nitride layer 135 after the first nitride layer 135 has been pre-cleaned.

In one or more embodiments, the inhibitor (SAM 150) is deposited by exposing the bottom 149 of the gap 146 to a hydrocarbon carried in an inert carrier gas, for example, argon (Ar) gas. In one or more embodiments, the inhibitor (SAM 150) comprises an alkylsilane or an alkyne. The SAM blocks deposition of a subsequent material on the first nitride material 135.

In some embodiments, selectively depositing the SAM comprises exposing the bottom of the gap to a silane or a hydrocarbon having the formula R₁—C≡C—R₂ or H—C≡C—R₃, wherein R1 and R2 can be the same of different and R1 and R2 are linear alkyl chains having from 1 to 15 carbon atoms and R3 is a linear alkyl chain comprising from 1 to 20 carbon atoms. In specific embodiments, the silane has a formula R—SiH₃, wherein R is selected from a linear alkyl chain and a branched alkyl chain comprising from 2 to 20 carbon atoms. In other specific embodiments, the hydrocarbon has the formula R₁—C≡C—R₂. In one specific embodiment, the hydrocarbon is 5-decyne. In other specific embodiments, the hydrocarbon has the formula H—C≡C—R₃.

In one or more embodiments, the inhibitor (SAM 150) comprises or consists essentially of an alkylsilane. In some embodiments, the alkylsilane comprises or consists essentially of one or more of octylsilane, nonasilane, decasilane, undecasilane, dodecylsilane, tridecylsilane, phenylsilane, 1,4-disilabutane, diethylsilane, diisopropylsilane, phenyldimethylsilane, triethylsilane, or tert-butyldimethylsilane.

In some embodiments, the substrate is soaked in a vapor of the inhibitor (SAM). In some embodiments, the processing conditions for exposing the substrate to the SAM may be controlled.

In some embodiments, the pressure of the processing chamber is controlled. The pressure of the processing chamber may be any suitable pressure for forming the blocking layer. In some embodiments, the pressure of the processing chamber is maintained at less than or equal to about 80 Torr, less than or equal to about 70 Torr, less than or equal to about 60 Torr, less than or equal to about 50 Torr, less than or equal to about 40 Torr, less than or equal to about 30 Torr, less than or equal to about 20 Torr, less than or equal to about 15 Torr, less than or equal to about 10 Torr, or less than or equal to about 5 Torr. In some embodiments, the pressure of the processing chamber is maintained at about 10 Torr, about 20 Torr, about 30 Torr, about 40 Torr, or about 50 Torr.

In one or more embodiments, a flow of argon (Ar) gas is configured to carry the SAM from a container to the processing chamber. In some embodiments, the flow rate of the argon (Ar) gas that is configured to carry the SAM into the processing chamber is controlled. The flow rate of the argon (Ar) gas may be any suitable flow rate for forming the passivation layer. In some embodiments, the flow rate of the argon (Ar) gas is in a range of about 50 sccm to about 100 sccm, or in a range of about 75 sccm to about 100 sccm. In one or more embodiments, the flow rate of the argon (Ar) gas is about 600 sccm. In some embodiments, the flow rate of the argon (Ar) gas is less than or equal to about 600 sccm, less than or equal to about 500 sccm, less than or equal to about 400 sccm, less than or equal to about 300 sccm, less than or equal to about 250 sccm, less than or equal to about 200 sccm, less than or equal to about 150 sccm, less than or equal to about 100 sccm, less than or equal to about 75 sccm, or less than or equal to about 50 sccm.

In some embodiments, the soak period, during which the SAM is exposed to the substrate, is controlled. The soak period may be any suitable period for forming the blocking layer. In some embodiments, the soak period is from 1 to 200s, for example from 1 to 10s, greater than or equal to about 10 s, greater than or equal to about 20 s, greater than or equal to about 30 s, greater than or equal to about 45 s, greater than or equal to about 60 s, greater than or equal to about 80 s, greater than or equal to about 120 s, greater than or equal to about 150 s, or greater than or equal to about 200 s. In some embodiments, the soak period is about 60 s. In some embodiments, the soak period is about 200 s.

In one or more embodiments, the SAM is in a liquid phase when the SAM is in a container, such as an ampoule or a cylinder, from which the SAM is delivered to the chamber in a carrier gas. In some embodiments, the SAM is in a saturated vapor phase in the container when the container has a pressure of about 0.1 torr. In one or more embodiments, the temperature of the container is lower than the temperature in the processing chamber. In one or more embodiments, a carrier gas such as argon (Ar) gas carries the saturated vapor phase SAM from the container to the processing chamber. In some embodiments, the temperature of the processing chamber is controlled during exposure to the SAM. The temperature of the processing chamber may also be referred to as the operating temperature. In some embodiments, the temperature of the processing chamber is in a range of about 150° C. to about 400° C., for example, 200° C. to about 300° C. In some embodiments, the temperature of the processing chamber during exposure to the inhibitor is less than or equal to 400°C., less than or equal to 350°C., less than or equal to 300° C., less than or equal to 275° C., less than or equal to 250° C., less than or equal to 225° C., or less than or equal to 200° C.

In a particular embodiment, the substrate is exposed to the inhibitor at a temperature in the range of 250 °C. to 350 °C., for a time in the range of 100 seconds to 300 seconds, at a pressure in the range of 20 Torr to 40 Torr, and a flow rate in the range of 200 sccm to 600 sccm.

Referring to FIG. 1D, a third nitride material 160 is shown on the SAM 150 and over the sidewalls 148. In one or more embodiments, the third nitride material 160 is the same material as the second nitride material (dielectric layer 145). In one or more embodiments, the third nitride material 160 forms on the sidewalls 148 and is substantially prevented from forming on the first nitride material surface 131 at the bottom 149 of the gap 146. In some embodiments, the pre-clean process following by the SAM substantially completely blocks formation of the third nitride material 160 on the first nitride material surface 131 at the bottom of the gap 146, and no barrier layer 160 material is deposited on the metal surface. In one or more embodiments, the third nitride material 160 is selectively deposited on at least a portion of the sidewalls 148. In one or more embodiments, the third nitride material 160 may cover the entirety of the sidewalls 148.

One of more embodiments of the disclosure including the pre-cleaning described herein provides special surface modification of the first nitride material surface 131 to further improve SAM selectivity. The thermal soak and plasma treatments described herein improve the selectivity. Embodiments significantly improve the SAM selectivity and eliminate the formation of third nitride material 160 on the first nitride material surface 131 resulting in greatly reduced via resistance.

In one or more embodiments, the third nitride material 160 is selectively deposited by atomic layer deposition (ALD) and has a thickness in a range of from about 2 Å to about 10 Å. In some embodiments, the third nitride material 160 is deposited in a single ALD cycle. In other embodiments, the third nitride material 160 is deposited in from 1 to 40 ALD cycles. In one or more embodiments, each cycle of the 1 to 40 ALD cycles is configured to deposit a thickness of about 0.5 Å of the third nitride material 160 with substantially no deposition on the first nitride material.

In a typical ALD process, alternating pulses or flows of “A” precursor and “B” precursor can be used to deposit a film. The alternating exposure of the surface to reactants “A” and “B” is continued until the desired thickness film is reached. However, instead of pulsing the reactants, the gases can flow simultaneously from one or more gas delivery head or nozzle and the substrate and/or gas delivery head can be moved such that the substrate is sequentially exposed to each of the reactive gases. Of course, the aforementioned ALD cycles are merely exemplary of a wide variety of ALD process cycles in which a deposited layer is formed by alternating layers of precursors and co-reactants.

In one or more embodiments, reactants and/or co-reactants are in vapor or gas form. The reactants may be delivered with a carrier gas. A carrier gas, a purge gas, a deposition gas, or other process gas may contain nitrogen, hydrogen, argon, neon, helium, or combinations thereof. The various plasmas described herein, such as the nitrogen plasma or the inert gas plasma, may be ignited from and/or contain a plasma co-reactant gas.

In one or more embodiments, the various gases for the process may be pulsed into an inlet, through a gas channel, from various holes or outlets, and into a central channel. In one or more embodiments, the deposition gases may be sequentially pulsed to and through a showerhead. Alternatively, as described above, the gases can flow simultaneously through gas supply nozzle or head and the substrate and/or the gas supply head can be moved so that the substrate is sequentially exposed to the gases.

In one or more embodiments, the third nitride material 160 and SAM are deposited using a multi-chamber process with separation of the third nitride material 160. In other embodiments, a single chamber approach is used, with all processes occurring within one chamber and the different layers/films separated in processing by gas purges.

Referring to FIG. 1E, in one or more embodiments, the inhibitor (SAM 150) has been removed from the first nitride material in structure shown in FIG. 1D using the methods described herein. In one or more embodiments, removing the inhibitor (SAM 150) comprises a plasma treatment process comprising flowing one or more of hydrogen (H₂) or argon (Ar). In one or more embodiments, the plasma treatment process comprises increasing a density of the third nitride material 160.

After formation of the third nitride material 160, the gap 146 is filled with a suitable conductive material. The gap fill process can occur with or without removal of the inhibitor (SAM 150). In one or more embodiments, a gap fill process comprises filling the gap 146 with one or more of copper (Cu) or cobalt (Co).

FIG. 2 illustrates a process flow diagram of a method 300 for forming a microelectronic device. FIG. 2 illustrates a method of forming any of the microelectronic devices of one or more embodiments shown in FIGS. 1A-1E . Referring to FIG. 2, the method 300 comprises, at operation 310, forming a first nitride material 135 on a substrate.

At operation 320, the method 300 comprises pre-cleaning the first nitride material 135 at the bottom of the gap 146, in particular the first nitride material surface 131 to remove impurities (e.g., native oxides) from the first nitride material surface 131.

At operation 330, the method 300 comprises selectively depositing an inhibitor (self-assembled monolayer (SAM) 150 ) on the bottom 149 of the gap 146. The inhibitor (SAM 150) selectively forming on the first nitride material 135 over the second nitride material 145 which makes up the sidewalls of the gap 146.

At operation 340, the method 300 comprises forming a third nitride material 160 on the sidewalls 148. At operation 340, the method 300 comprises selectively depositing a third nitride material 160 on the sidewalls 148 of the gap 146. At operation 340, in some embodiments, the third nitride material 160 is deposited at a thickness on the sidewalls but not on the first nitride material surface 131, or first nitride material 135. As used in this manner, depositing on a material means that there is some chemical interaction between at least some of the stated material being deposited with the stated material being deposited upon.

At operation 350, the method 300 comprises removing the inhibitor (SAM 150) after selectively depositing the third nitride material 160 on the sidewalls 148 of the gap 146.

At operation 360, the method 300 comprises performing a gap fill process in the gap 146. The gap fill process can include forming one or more of a via and a line to form an interconnect in the device.

In one or more embodiments, the methods described herein comprise an optional post-processing operation. The optional post-processing operation can be, for example, a process to modify film properties (e.g., annealing) or a further film deposition process (e.g., additional ALD or CVD processes) to grow additional films. In some embodiments, the optional post-processing operation can be a process that modifies a property of the deposited film. In some embodiments, the optional post-processing operation comprises annealing the as-deposited film. In some embodiments, annealing is done at temperatures in the range of about 300°C., 400°C., 500°C., 600°C., 700°C., 800°C., 900°C. or 1000°C. The annealing environment of some embodiments comprises one or more of an inert gas (e.g., molecular nitrogen (N₂), argon (Ar)) or a reducing gas (e.g., molecular hydrogen (H₂) or ammonia (NH₃)) or an oxidant, such as, but not limited to, oxygen (O₂), ozone (O₃), or peroxides. Annealing can be performed for any suitable length of time. In some embodiments, the film is annealed for a predetermined time in the range of about 15 seconds to about 90 minutes, or in the range of about 1 minute to about 60 minutes.

In some embodiments, the substrate is moved from a first chamber to a separate, next chamber for further processing. The substrate can be moved directly from the first chamber to the separate processing chamber, or the substrate can be moved from the first chamber to one or more transfer chambers, and then moved to the separate processing chamber. In some embodiments, the deposition of the barrier layer and the dopant film can be done in a single chamber, and then the post-processing can be performed in a separate chamber. Accordingly, the processing apparatus may comprise multiple chambers in communication with a transfer station. An apparatus of this sort may be referred to as a “cluster tool” or “clustered system”, and the like.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. Two well-known cluster tools which may be adapted for the present disclosure are the Centura® and the Endura®, both available from Applied Materials, Inc., of Santa Clara, Calif. However, the exact arrangement and combination of chambers may be altered for purposes of performing specific steps of a process as described herein. Other processing chambers which may be used include, but are not limited to, cyclic deposition including a deposition step, and an annealing or treatment step, atomic layer deposition (ALD), chemical vapor deposition (CVD), physical vapor deposition (PVD), etch, pre-clean, chemical clean, plasma nitridation, degas, orientation, hydroxylation and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions, and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants (e.g., reactant). According to one or more embodiments, a purge gas is injected at the exit of the deposition chamber to prevent reactants (e.g., reactant) from moving from the deposition chamber to the transfer chamber and/or additional processing chamber. Thus, the flow of inert gas forms a curtain at the exit of the chamber.

The substrate can be processed in single substrate deposition chambers, where a single substrate is loaded, processed and unloaded before another substrate is processed. The substrate can also be processed in a continuous manner, similar to a conveyer system, in which multiple substrates are individually loaded into a first part of the chamber, move through the chamber and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, cleaning, etc. processes throughout the carousel path.

During processing, the substrate can be heated or cooled. Such heating or cooling can be accomplished by any suitable means including, but not limited to, changing the temperature of the substrate support and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled to locally change the substrate temperature. In some embodiments, a heater/cooler is positioned within the chamber adjacent the substrate surface to convectively change the substrate temperature.

The substrate can also be stationary or rotated during processing. A rotating substrate can be rotated (about the substrate axis) continuously or in discrete steps. For example, a substrate may be rotated throughout the entire process, or the substrate can be rotated by a small amount between exposures to different reactive or purge gases. Rotating the substrate during processing (either continuously or in steps) may help produce a more uniform deposition or etch by minimizing the effect of, for example, local variability in gas flow geometries.

Another aspect of the disclosure pertains to a non-transitory computer readable medium including instructions, that, when executed by a controller of a processing system, causes the processing system to perform operations of the methods described herein. In one embodiment, a non-transitory computer readable medium including instructions, that, when executed by a controller of a processing system, causes the processing system to perform operations of the methods described herein with respect to FIGS. 1A-E and 2.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of selectively depositing a film, the method comprising:
exposing a substrate to an inhibitor to selectively passivate a first nitride material relative to a second nitride material, the first nitride material being different from the second nitride material; and
depositing a third nitride material on the second nitride material.

2. The method of claim 1, wherein the inhibitor is a self-assembled monolayer.

3. The method of claim 2, wherein the inhibitor comprises one or more of an alkyne or an alkylsilane.

4. The method of claim 3, wherein the inhibitor consists essentially one or more of octylsilane, nonasilane, decasilane, undecasilane, dodecylsilane, tridecylsilane, phenylsilane, 1,4-disilabutane, diethylsilane, diisopropylsilane, phenyldimethylsilane, triethylsilane, or tert-butyldimethylsilane.

5. The method of claim 4, wherein the substrate is soaked with the inhibitor at a temperature less than 400°C.

6. The method of claim 5, wherein soaking the substrate with the inhibitor occurs at a temperature in the range of 250°C. to 350°C., for a time in the range of 100 seconds to 300 seconds, at a pressure in the range of 20 Torr to 40 Torr, and a flow rate in the range of 200 sccm to 600 sccm.

7. The method of claim 1, wherein the first nitride material consists essentially of titanium nitride (TiN) and the second nitride material consists essentially of silicon nitride (SiN).

8. The method of claim 7, wherein the third nitride material consists essentially of silicon nitride (SiN).

9. The method of claim 1, wherein the third nitride material consists essentially of the same material as the second nitride material.

10. The method of claim 1, further comprising removing surface oxides from the first nitride material prior to exposure to the inhibitor.

11. The method of claim 10, wherein removing the surface oxides comprises exposing the substrate to a hydrogen (H₂) plasma.

12. The method of claim 1, further comprising removing the inhibitor after deposition of the third nitride material.

13. The method of claim 12, wherein removing the inhibitor comprises exposing the substrate to a hydrogen (H₂) plasma.

14. The method of claim 1, wherein the third nitride material is deposited to a thickness of 20 Å on the second nitride material with substantially no deposition on the first nitride material.

15. A method of selectively depositing a film, the method comprising:
forming a self-assembled monolayer of an inhibitor in a structure on a substrate, the structure having a bottom of a first nitride material and sidewalls of a second nitride material, the self-assembled monolayer forming on the first nitride material selectively over the second nitride material, the first nitride material being different from the second nitride material; and
depositing a third nitride material on the second nitride material.

16. The method of claim 15, wherein the inhibitor comprises one or more of an alkyne or an alkylsilane.

17. The method of claim 16, wherein the inhibitor consists essentially of one or more of octylsilane, nonasilane, decasilane, undecasilane, dodecylsilane, tridecylsilane, phenylsilane, 1,4-disilabutane, diethylsilane, diisopropylsilane, phenyldimethylsilane, triethylsilane, or tert-butyldimethylsilane.

18. The method of claim 15, wherein the first nitride material consists essentially of titanium nitride (TiN), the second nitride material consists essentially of silicon nitride (SiN), and the third nitride material consists essentially of silicon nitride (SiN).

19. The method of claim 15, further comprising removing surface oxides from the first nitride material prior to forming the self-assembled monolayer by exposing the substrate to a hydrogen (H₂) plasma.

20. The method of claim 15, further comprising removing the self-assembled monolayer after deposition of the third nitride material by exposing the substrate to a hydrogen (H₂) plasma.
